(19) United States
(12) Patent Application Publication
(10) Pub. No.: US 2014/0375322 A1
(43) Pub. Date: Dec. 25, 2014

(54) TEST SYSTEM AND METHOD FOR TESTING BACKLIGHT UNIT OF ELECTRONIC DEVICE

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: JIAN SUN, Shenzhen (CN); LAI-JUN LIU, Shenzhen (CN)

(73) Assignee: HON HAI PRECISION INDUSTRY CO., LTD., New Taipei (TW)

(21) Appl. No.: 14/308,901

(22) Filed: Jun. 19, 2014

(30) Foreign Application Priority Data
Jun. 19, 2013 (CN) 2013102424545

(51) Int. Cl. G01R 31/44; G06F 3/0484; G06F 3/0482; G09G 3/34

(52) U.S. Cl. CPC G01R 31/44; G09G 3/3406; G06F 3/04842; G06F 3/0482
USPC 324/414

(57) ABSTRACT

A test system and a method for testing a backlight unit of an electronic device are provided. The test system includes a selection unit, a backlight control unit, a display control unit, a determination unit and a count unit. The selection unit selects one mode of a number of modes and issues a command. The backlight control unit controls the backlight unit to adjust a luminous intensity. The display control unit controls the display unit to display a selection dialog window showing a number of options corresponding to the number of modes, and the options are displayed in random order. When an option is chosen, the determination unit determines whether the actual change of the luminous intensity of the backlight unit matches the command. The count unit counts a first counting value and a second counting value and determines whether the backlight unit is qualified.

### CROSS-REFERENCE TO RELATED APPLICATIONS

This application claims priority to Chinese Patent Application No. 201310242454.5 filed on Jun. 19, 2013 in the China Intellectual Property Office, the contents of which are incorporated by reference herein.

### FIELD

The present disclosure relates to test systems and methods and more particularly to a test system and a method for testing backlight of an electronic device.

### BACKGROUND

A backlight unit of an electronic device must be tested to make sure that the backlight unit is functional after the electronic device is assembled. Usually, the backlight unit is tested by an operator.

### BRIEF DESCRIPTION OF THE DRAWINGS

The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a block diagram of an embodiment of an electronic device.

FIG. 2 is a selection dialog window displayed on a display unit of FIG. 1.

FIG. 3 is a confirmation dialog window displayed on a display unit of FIG. 1.

FIG. 4 is a flowchart of an embodiment of a test method for testing a backlight unit of an electronic device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure is described in relation to a test system and a method for testing a backlight unit of an electronic device. The test system includes a selection unit, a backlight control unit, a display control unit, a determination unit and a count unit. The selection unit selects one mode and issues a command. The backlight control unit controls the backlight unit to adjust the luminous intensity. The display control unit controls the display unit to display a selection dialog window showing a number of options corresponding to a plurality of modes, and the options are displayed in random order. When an option is chosen, the determination unit determines whether the actual change of the luminous intensity of the backlight unit matches the command. The count unit counts a first counting value and a second counting value and determines whether the backlight unit is qualified.

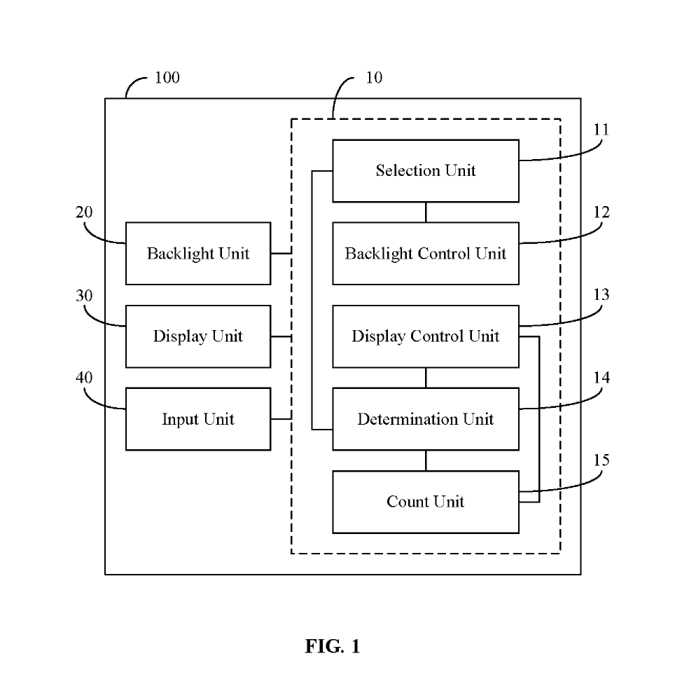

FIG. 1 illustrates an embodiment of an electronic device 100. The electronic device 100 can include a test system 10, a backlight unit 20, a display unit 30 and an input unit 40. The backlight unit 20, the display unit 30, and the input unit 40 are electrically coupled to the test system 10. The test system 10 is used to test the backlight unit 20 to determine whether the backlight unit 20 is qualified.

The test system 10 includes a selection unit 11, a backlight control unit 12, a display control unit 13, a determination unit 14 and a count unit 15. The backlight unit 20 can operate in one of a plurality of brightness-changing modes (hereinafter “modes”). The selection unit 11 randomly selects one mode of the plurality of modes and issues a command associated with the selected mode. In at least one embodiment, the backlight unit 20 can operate in a decreasing mode, an increasing mode, or a steady mode. The selection unit 11 issues a decrease brightness command when the decreasing mode is selected, and issues an increase brightness command when the increasing mode is selected.

The backlight control unit 12 controls the backlight unit 20 to adjust a luminous intensity according to the command issued by the selection unit 11. In at least one embodiment, the backlight control unit 12 controls the backlight unit 20 to decrease the luminous intensity according to the decrease brightness command, and controls the backlight unit 20 to increase the luminous intensity according to the increase brightness command. If no command is issued, the luminous intensity of the backlight unit 20 remains unchanged.

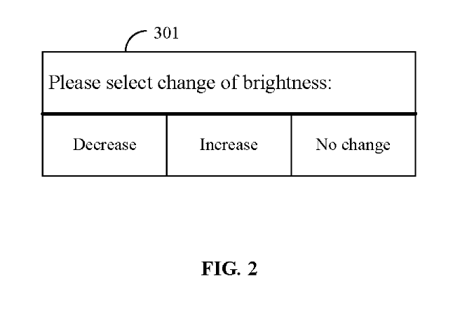

Referring to FIG. 2, the display control unit 13 controls the display unit 30 to display a selection dialog window 301 after the backlight control unit 12 has controlled the backlight unit 20 according to the command. The selection dialog window 301 displays a plurality of options in random order, and each option corresponds to one of the plurality of modes. In at least one embodiment, the option “Increase” is displayed between the options “Decrease” and “No change” corresponding to the increase brightness command. In an alternative embodiment, the options can be displayed in other orders in the selection dialog window 301. An operator can choose an option through the input unit 40 according to an actual change of the luminous intensity of the backlight unit 20. The input unit 40 issues an input signal in response to the chosen option.

The determination unit 14 determines whether the actual change of the luminous intensity of the backlight unit 20 associated with the chosen option matches the command associated with the selected mode. After the determination unit 14 determines whether the actual change matches the command, the selection unit 11 randomly selects a mode, and the test system 10 repeats the test.

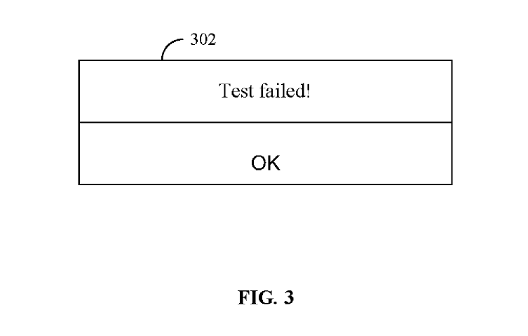

In at least one embodiment, the count unit 15 counts a first counting value when the actual change is different from the command, and counts a second counting value when the actual change matches the command. An initial counting value of the first counting value and the second counting value is 0, and the count unit 15 increases the first counting value or the second counting value by 1 after each test. The count unit 15 determines whether the first counting value is equal to a first preset value, and whether the second counting value is equal to a second preset value. When the first counting value is equal to the first preset value, the display control unit 13 controls the display unit 30 to display a confirmation dialog window 302 (shown in FIG. 3) showing a “Test failed!” message, and the backlight unit 20 is determined to be unqualified. When the second counting value is equal to the second preset value, the display control unit 13 controls the display unit 30 to display the confirmation dialog window 302 showing a “Test passed!” message, and the backlight unit 20 is determined to be qualified.

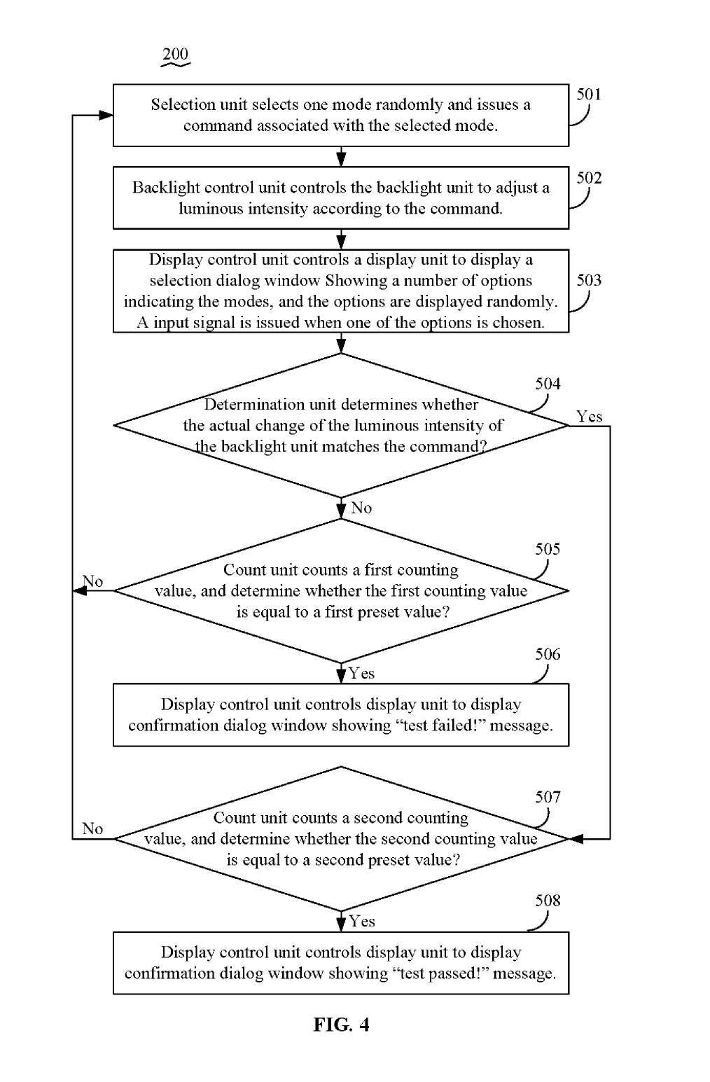

Referring to FIG. 4, a flowchart of an embodiment of an example method 200 is presented. The example method 200 is provided by way of example, as there are a variety of ways to carry out the embodiment. The example method 200 described below can be carried out using the configurations illustrated in FIG. 1, and various elements of these figures are referenced in explaining the example method 200. Each block shown in FIG. 4 represents one or more processes, methods, or subroutines, carried out in the exemplary method 200. Additionally, the illustrated order of blocks is by example only and the order of the blocks can change. The example method 200 can begin at block 501.

At block 501, a selection unit selects one mode of a plurality of modes randomly, and issues a command associated with the selected mode. In at least one embodiment, a backlight unit can operate in a decreasing mode, an increasing mode, or a steady mode. The selection unit issues a decrease brightness command when the decreasing mode is selected, and issues an increase brightness command when the increasing mode is selected.

At block 502, a backlight control unit controls the backlight unit to adjust a luminous intensity according to the command issued by the selection unit. In at least one embodiment, the backlight control unit controls the backlight unit to decrease the luminous intensity according to the decrease brightness command, and controls the backlight unit to increase the luminous intensity according to the increase brightness command. If no command is issued, the luminous intensity of the backlight unit remains unchanged.

At block 503, a display control unit controls a display unit to display a selection dialog window after the backlight control unit has controlled the backlight unit according to the command. The selection dialog window displays a plurality of options in random order, and each option corresponds to one of the plurality of modes. In at least one embodiment, the option “Increase” is displayed between the options “Decrease” and “No change” corresponding to the increase brightness command. In an alternative embodiment, the options can be displayed in other orders in the selection dialog window. An operator can choose an option through an input unit according to an actual change of the luminous intensity of the backlight unit. The input unit issues an input signal in response to the chosen option.

At block 504, a determination unit determines whether the actual change of the luminous intensity of the backlight unit associated with the chosen option matches the command associated with the selected mode. If yes, block 507 is implemented; otherwise, if the actual change of the luminous intensity of the backlight unit is different from the command, block 505 is implemented.

At block 505, a count unit counts a first counting value. An initial counting value of the first counting value is 0, and the count unit increases the first counting value by 1 after each test. The count unit determines whether the first counting value is equal to a first preset value. If the first counting value is less than the first preset value, the block 501 is implemented. If the first counting value is equal to the first preset value, block 506 is implemented.

At block 506, the display control unit controls the display unit to display a confirmation dialog window showing a “Test failed!” message, and the backlight unit is determined to be unqualified.

At block 507, the count unit counts a second counting value. An initial counting value of the second counting value is 0, and the count unit increases the second counting value by 1 after each test. The count unit determines whether the second counting value is equal to a second preset value. If the second counting value is less than the second preset value, block 501 is implemented. If the second counting value is equal to the second preset value, block 508 is implemented.

At block 508, the display control unit controls the display unit to display the confirmation dialog window showing a “Test passed!” message, and the backlight unit is determined to be qualified.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in particular matters of shape, size and arrangement of the parts within the principles of the present disclosure, up to and including the full extent established by the broad general meaning of the terms used in the claims.

What is claimed is:

1. An electronic device with a backlight unit test function, the electronic device comprising:
a backlight unit;
a display unit;
a selection unit configured to select one mode of a plurality of modes of the backlight unit and issues a command associated with the selected mode;
a backlight control unit configured to control the backlight unit to adjust a luminous intensity according to the issued command;
a display control unit configured to control the display unit to display a selection dialog window showing a plurality of options corresponding to the plurality of modes, and the plurality of options are displayed in the selection dialog window in random order;
an input unit configured to issue an input signal when one of the plurality of options is chosen;
a determination unit configured to determine whether the actual change of the luminous intensity of the backlight unit associated with the chosen option matches the command associated with the selected mode; and
a count unit configured to counts a first counting value when the actual change is different from the command, and counts a second counting value when the actual change matches the command, determine the backlight unit is unqualified when the first counting value is equal to a first preset value, and determine the backlight unit is qualified when the second counting value is equal to a second preset value.

2. The electronic device of claim 1, wherein an initial counting value of the first counting value and the second counting value is 0, and the count unit increases the first counting value or the second counting value by 1 after each test.

3. The electronic device of claim 1, wherein the display control unit controls the display unit to display a confirmation dialog window showing a test failed message when the first counting value is equal to the first preset value, and display the confirmation dialog window showing a test passed message when the second counting value is equal to the second preset value.

4. The electronic device of claim 1, wherein the input signal is issued associated with the chosen option, and the option is chosen according to the actual change of the luminous intensity of the backlight unit.

5. A test system for testing a backlight unit of an electronic device, the test system comprising:
a selection unit configured to select one mode of a plurality of modes of the backlight unit and issues a command associated with the selected mode;
a backlight control unit configured to control the backlight unit to adjust a luminous intensity according to the issued command;
a display control unit configured to control the display unit to display a selection dialog window showing a plurality of options corresponding to the plurality of modes, and the plurality of options are displayed in the selection dialog window in random order, an input signal is issued when one mode of the plurality of options is chosen;
a determination unit configured to determine whether the actual change of the luminous intensity of the backlight unit associated with the chosen option matches the command associated with the selected mode; and
a count unit configured to counts a first counting value when the actual change is different from the command, and counts a second counting value when the actual change matches the command, determine the backlight unit is unqualified when the first counting value is equal to a first preset value, and determine the backlight unit is qualified when the second counting value is equal to a second preset value.

6. The test system of claim 5, wherein an initial counting value of the first counting value and the second counting value is 0, and the count unit increases the first counting value or the second counting value by 1 after each test.

7. The test system of claim 5, wherein the display control unit controls the display unit to display a confirmation dialog window showing a test failed message when the first counting value is equal to the first preset value, and display the confirmation dialog window showing a test passed message when the second counting value is equal to the second preset value.

8. The test system of claim 5, wherein the input signal is issued associated with the chosen option, and the option is chosen according to the actual change of the luminous intensity of the backlight unit.

9. A test method for testing a backlight unit of an electronic device, the test method comprising:
selecting one mode of a plurality of modes of the backlight unit and issues a command associated with the selected mode;
controlling the backlight unit to adjust a luminous intensity according to the issued command;
controlling a display unit to display a selection dialog window showing a plurality of options corresponding to the plurality of modes, and the plurality of options are displayed in the selection dialog window in random order, an input signal is issued when one mode of the plurality of options is chosen;
determining whether the actual change of the luminous intensity of the backlight unit associated with the chosen option matches the command associated with the selected mode; and
counting a first counting value when the actual change is different from the command, and counting a second counting value when the actual change matches the command, determining the backlight unit is unqualified when the first counting value is equal to a first preset value, and determining the backlight unit is qualified when the second counting value is equal to a second preset value.

10. The test method of claim 9, wherein counting a first counting value when the actual change is different from the command, and counting a second counting value when the actual change matches the command, determining the backlight unit is unqualified when the first counting value is equal to a first preset value, and determining the backlight unit is qualified when the second counting value is equal to a second preset value comprising an initial counting value of the first counting value and the second counting value is 0, and increasing the first counting value or the second counting value by 1 after each test.

11. The test method of claim 9, wherein counting a first counting value when the actual change is different from the command, and counting a second counting value when the actual change matches the command, determining the backlight unit is unqualified when the first counting value is equal to a first preset value, and determining the backlight unit is qualified when the second counting value is equal to a second preset value comprising controlling the display unit to display a confirmation dialog window showing a test failed message when the first counting value is equal to the first preset value, and display the confirmation dialog window showing a test passed message when the second counting value is equal to the second preset value.
